(19) United States
(12) Patent Application Publication
(10) Pub. No.: US 2005/0052155 A1
(43) Pub. Date: Mar. 10, 2005

(54) Battery array and process for controlling the state of charge of a battery array

(76) Inventor: Andreas Surig, Krummesse (DE)

Correspondence Address: MCGLEW & TUTTLE, PC, 1 SCARBOROUGH STATION PLAZA, SCARBOROUGH, NY, 10510-0827, US

(21) Appl. No.: 10/932,424

(22) Filed: Sep. 2, 2004

(30) Foreign Application Priority Data
Sep. 6, 2003 (DE) 103 41 188.7

(51) Int. Cl. G11C 11/34

(52) U.S. Cl. 320/116

(57) ABSTRACT

A battery array is provided for connection to an electric load as well as to a battery charger. A process for controlling the state of charge of a battery array is also provided. The energy needed to supply an electric device not connected to the electric network is taken from a battery, which is composed of a plurality of galvanic cells connected in series. The energy that can be supplied by such a series-connected array, a so-called battery line, is limited for safety reasons. Moreover, it is difficult to determine the state of charge, because the calibration points necessary for the determination of the state of charge, namely, the two states of charge “full” and “empty,” are reached by such a series-connected array only rarely if ever. A battery array that has a plurality of series-connected arrays connected in parallel, whose states of charge are estimated separately is provided. The corresponding process controls the state of charge of the battery array, in which the individual series-connected arrays are charged and discharged in a preset sequence.

### CROSS REFERENCE TO RELATED APPLICATIONS

This application claims the benefit of priority under 35 U.S.C. § 119 of German patent application DE 103 41 188.7 filed Sep. 9, 2003, the entire contents of which are incorporated herein by reference.

### FIELD OF THE INVENTION

The present invention pertains to a battery array for connection to an electric load as well as to a battery charger and to a process for controlling the state of charge of a battery array.

### BACKGROUND OF THE INVENTION

The energy necessary for supplying an electric device not connected to an electric network is usually taken from a battery, which is composed of a plurality of galvanic cells connected in series. The adaptation to the energy demand of the device, i.e., the electric load, is performed by selecting the number of cells connected in series and by selecting cells with a suitable nominal capacity. The nominal capacity is the amount of electricity that is associated with a cell during discharge under nominal conditions, i.e., with preset values for the discharging current, the discharge time, the final discharge voltage, the temperature, the density of the electrolyte and the electrolyte filling level. With the nominal voltage of an individual cell, which is a fixed value depending on the system and is, e.g., 1.2 V for a nickel-cadmium cell, and the number of cells connected in series, the energy that can be supplied by the battery during discharge under nominal conditions is obtained as the product of the number of cells connected in series, the nominal capacity and the nominal voltage of an individual cell. The energy that can be supplied by the battery shall be selected to be higher than the energy needed to supply the device. The battery is adapted at first to the voltage required for the connected device. The subsequent adaptation to the energy demand of the device is performed by selecting the nominal capacity. In nickel-cadmium cells and nickel hydride cells, in particular, the nominal capacity cannot be increased arbitrarily as desired by the parallel connection of a plurality of these cells because of the electrochemical conditions and for safety reasons. The energy that can be supplied by an individual cell is also limited for the construction of explosion-proof, intrinsically safe batteries and battery packs, because the nominal capacity of one cell must not, as a rule, exceed a certain limit if the cell is not to become a source of ignition. At a constant voltage as the product of the number of cells and the nominal voltage of the cells, an upper limit is thus set for the energy that can be supplied by a series-connected, explosion-proof battery array.

The accurate determination of the state of charge, in which the determination of the current capacity will hereinafter also be included, is not possible during the operation of a rechargeable electrochemical battery, especially in the case of batteries that are composed of nickel-cadmium cells and nickel hydride cells by the measurement of electric variables that can be determined from the outside, for example, the voltage. The charging current and the discharging current flowing into the battery are balanced to obtain at least usable estimates for the state of charge. However, this leads to considerable summation errors over time, especially if the calibration points necessary for the process, namely, the two states of charge, namely, “full” and “empty,” are reached by the battery only rarely at best.

The discharging of batteries, which is always only partial, or the overcharging of batteries may have an adverse effect on the operating behavior of the battery in the lung run. For example, the so-called “memory effect” in nickel-cadmium cells shall be mentioned. If the cells are always discharged only partially or overcharged with lower currents over a long period of time, the terminal voltage of these cells decreases because of internal electrochemical processes. At a preset final discharge voltage, this leads to the premature switching off of the cell and thus to reduced operating times. The user is therefore often advised to completely discharge the battery in order to avoid the memory effect.

Nickel-cadmium batteries and nickel hydride batteries are charged with constant current. Recognizing the state of charge is problematic. A plurality of measured variables, especially the temperature rise and the voltage curve, but, e.g., also the charging time and the charge taken up, are usually evaluated for this purpose. The temperature rise and the voltage curve as important measured variables are distinctly pronounced only if the charging current is above a certain threshold relative to the nominal capacity of the cell.

A battery charger that is used to supply a plurality of battery groups that are connected in series with one another and are connected to an electric load is known from EP 0 769 837 B1. The battery charger comprises a battery charge control unit for controlling the charging process, the battery charge control unit operating in a charging cycle that comprises a charge mode, a short discharge mode and a rest mode, and it brings this about in such a time-sharing operation that at least one of the battery groups is in the rest mode at any point in time during the charging process for the plurality of battery groups.

EP 0 913 268 B1 describes a process for maintaining the charging capacity of battery modules connected in series, wherein complete charging of at least one battery module takes place under the control effect of a programmed processor, but the other battery modules are not charged, and a subsequent partial discharge of this at least one module, but not of the other modules, takes place.

EP 0 746 895 B1 describes a battery with memory for storing charging methods, which are based on charging parameters such as voltage level data and the charging capacity data.

### SUMMARY OF THE INVENTION

The object of the present invention is to present a battery array that supplies a high energy and is sufficiently explosion-proof. Furthermore, an object of the present invention is to provide a process for controlling the state of charge of a battery array with which the readiness for use and the service life of the battery array are optimized.

The object is accomplished according to the present invention by a battery array according to the invention and a corresponding process for controlling the state of charge of a battery array.

According to the invention, the battery array can be connected to an electric load, for example, a portable electric gas-measuring device, as well as to a battery charger. The battery charger may be, for example, a constant current source supplied from the external electric network. The battery array comprises a plurality of battery lines that are connected in parallel and are each composed of a plurality of galvanic cells connected in series. A battery line composed up of a single cell is also conceivable. For example, nickel-cadmium cells or nickel hydride cells are used as galvanic cells. A measuring unit for estimating the state of charge is associated with each battery line. The measuring unit for estimating the state of charge measures values, e.g., for the voltage present on the battery line or the temperature, for determining the state of charge of the battery line, from which an indicator for the energy that can be supplied from the battery line to the electric device can be derived. The battery array comprises, moreover, an evaluating and control unit, to which the values measured by the measuring units for estimating the state of charge are sent. The evaluating and control unit calculates from this a value for the state of charge of the battery lines, which permits the state of charge of the battery lines to be estimated. A plurality of switches, which are arranged between a battery line each and the electric load, as well as a plurality of switches, which are arranged between a battery line and the battery charger, are actuated by the evaluating and control unit for opening and closing on the basis of this evaluation.

The process for controlling the state of charge of a battery array comprises a plurality of steps. Values, for example, the temperature change or the voltage curve on the galvanic cells, are measured at first by each measuring unit for estimating the state of charge of a battery line. The measured values are sent to the evaluating and control unit. The evaluating and control unit calculates from the values sent to it an estimate for the state of charge of the battery lines and determines therefrom either the battery line with the highest state of charge or the battery line with the lowest state of charge or both. When the battery array is connected to an electric load, the switch that is arranged between the battery line with the highest charge and the electric load is actuated by the evaluating and control unit for closing. When the battery array is connected to a battery charger, the switch that is arranged between the battery line with the lowest charge and the battery charger is actuated by the evaluating and control unit for closing. All other switches are actuated for opening. As soon as the battery line with the highest charge has released its charge completely to the electric load or the battery line with the lowest charge has been completely charged by the battery charger, the corresponding signal is recognized by the evaluating and control unit, and the sequence described is started again from the beginning, i.e., the measuring units for estimating the states of charge of the battery lines send new values for determining the states of charge to the evaluating and control unit, the consequence of which is again a corresponding actuation of the switches.

In an advantageous embodiment of the battery array, the energy that can be supplied by an individual battery line is selected, in adaptation to the electric load that can be connected, preferably a gas-measuring device, such that it will be consumed for a typical use of the electric load within a period of time for which the state of charge of the battery line can be reliably determined by the corresponding measuring unit for estimating the state of charge of the battery line and the evaluating and control unit.

If more than one battery line assumes the state of highest charge, the battery line whose discharge had happened the longest time ago is selected to release its charge to the electric load in a preferred embodiment of the process.

In another preferred embodiment of the process, the battery line whose charging had happened the longest time ago is correspondingly selected to take up charge from the battery charger in case more than one battery line assumes the lowest state of charge.

The following advantages arise, in general, from the present invention:

Due to the sequential clearing of a plurality of battery lines connected in parallel, it is possible to create battery arrays that supply a high energy and yet meet the requirements on intrinsic safety. The special sequence during the clearing guarantees, moreover, the uniform loading of the battery lines and consequently a longer service life of the battery array.

The estimation of the state of charge can be performed substantially more reliably, because it is carried out on smaller units, i.e., the individual battery lines. The two calibration points necessary for the estimation, namely, the two states of load “full” and “empty” of an individual battery line, are assumed, statistically speaking, more frequently.

Due to the design of the battery array with a plurality of battery lines, an electric load connected thereto can continue to be supplied by the other battery lines in case of failure of one battery line, as a result of which the reliability of the battery array is increased.

One possible application of the present invention is the supply of a portable gas-measuring device by a battery array. The gas-measuring device shall be able to be supplied with energy uninterruptedly for 12 hours. A battery array herefor is always designed such that the energy that can be supplied is sufficient for 15 hours in order to make allowances for aging effects. Consequently, a 25% reserve is maintained. A usual duration of use of the gas-measuring device is 8 hours, the duration of one work shift. The battery array is then usually charged completely. Consequently, only a good half of the energy that can be supplied is discharged, and the calibration point “empty” is reached only rarely if ever. It is therefore difficult to estimate the state of charge of the battery array. If the energy that can be supplied by the battery array is now distributed according to the present invention in equal parts among three battery lines arranged in parallel, which will be discharged and charged completely one after another, at least one battery line will be completely discharged in case of a usual use time of 8 hours. The calibration point “empty,” which is important for the estimation of the state of charge, will already have been reached at least once for all three battery lines after three uses.

The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which a preferred embodiment of the invention is illustrated.

### BRIEF DESCRIPTION OF THE DRAWINGS

FIG. 1 is a schematic view of a battery array according to the present invention;

FIG. 2 is a diagram of time curves of the voltage on the battery lines as well as an electric load connected to the battery array; and

FIG. 3 is a diagram of time curves of the voltage on the battery lines as well as on an electric load connected to the battery array, wherein no battery charger is connected to the battery array.

### DESCRIPTION OF THE PREFERRED EMBODIMENT

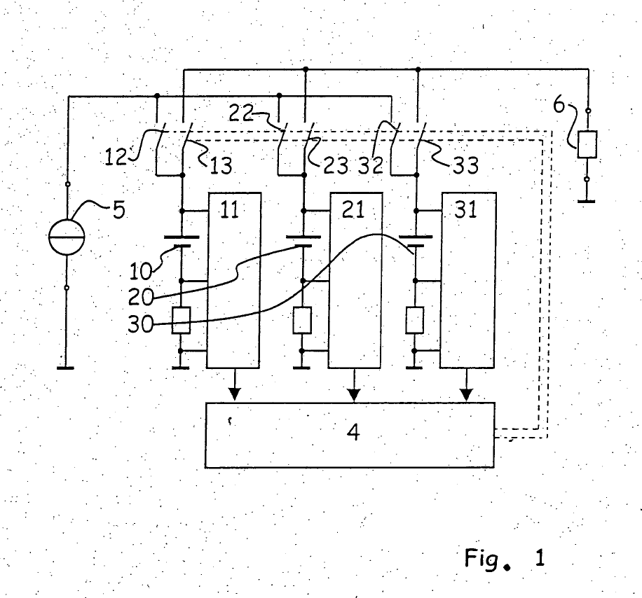

FIG. 1 shows a battery array according to the present invention with three battery lines 10, 20, 30 connected in parallel. Each battery line 10, 20, 30 is composed of one or more galvanic cells connected in series and connected to a measuring unit 11, 21, 31 for estimating the state of charge of the corresponding battery line 10, 20, 30. The three measuring units 11, 21, 31 for estimating the state of charge are connected to an evaluating and control unit 4. The battery lines 10, 20, 30 are connected to a battery charger 5 via feed lines, in which a switch 12, 22, 32 each is arranged. If a switch 12, 22, 32 is made (closed), the corresponding battery line 10, 20, 30 is charged by the battery charger 5. If the switch 12, 22, 32 is opened, as is shown in FIG. 1, the feed line of the battery line 10, 20, 30 to the battery charger 5 is interrupted, and charging is not possible. Moreover, the battery lines 10, 20, 30 are connected to an electric load 6 by feed lines, in which a respective switch 13, 23, 33 is arranged. If the switch 13, 23, 33 is made (closed), the corresponding battery line 10, 20, 30 is discharged to the electric load 6. If the switch 13, 23, 33 is opened, as is shown in FIG. 1, the feed line of the battery line 10, 20, 30 to the electric load 6 is interrupted and discharge is not possible. The switches 12, 22, 32 and 13, 23, 33 can be actuated by the evaluating and control unit 4 for opening and closing.

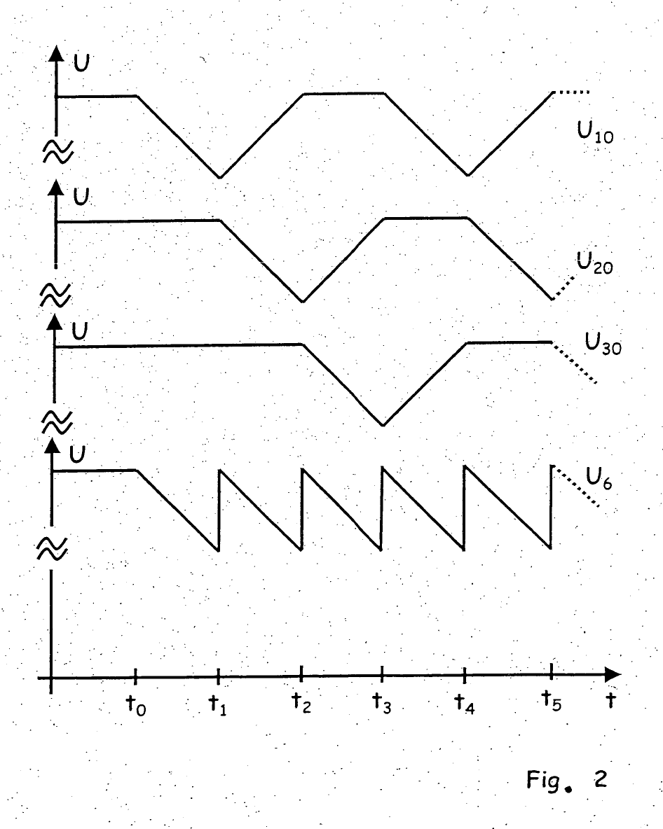

FIG. 2 shows the time curves of the voltage U₁₀, U₂₀, U₃₀, U₆ on the battery lines 10, 20, 30 as well as on the electric load 6 shown in FIG. 1, which is connected to the battery array. The battery line is being discharged at time t₀ to the electric load 6, it is completely discharged at time t₁ and will be recharged by the battery charger 5, while the battery line 20 is being discharged to the electric load 6. The battery line 10 is completely charged and the battery line 20 is completely discharged at time t₂ and will be recharged, while the battery line 30 is being discharged to the electric load 6. The battery line 20 is completely charged and the battery line 30 is completely discharged at time t₃ and will be recharged, while the battery line 10 is being discharged. At time t₄, the battery line 30 is completely charged and the battery line 10 is completely discharged. The voltage curves U₁₀, U₂₀, U₃₀ will now recur cyclically at the interval t₁, t₄.

The underlying principle of selection of the process according to the present invention for controlling the battery array is the charging of a battery line 10, 20, 30 when the voltage curve U₁₀, U₂₀, U₃₀ of that battery has assumed a minimum, when it had not been charged any longer for the longest time and the battery array is connected to a battery charger 5, and the discharge of a battery line 10, 20, 30 when the voltage curve U₁₀, U₂₀, U₃₀ of that battery has assumed a maximum, it had not been discharged any longer for the longest time and the battery array is connected to an electric load 6. The values that the voltage curves U₁₀, U₂₀, U₃₀ assume can be considered to be an indicator of the charge level of the corresponding battery lines 10, 20, 30. The voltage curve U₆ belonging to the electric load 6 is obtained by the superimposition of the voltage curves U₁₀, U₂₀, U₃₀.

The case in which the battery array is connected either only to an electric load 6 or only to a battery charger 5 but not to both components at the same time is relevant, as a rule, for practice.

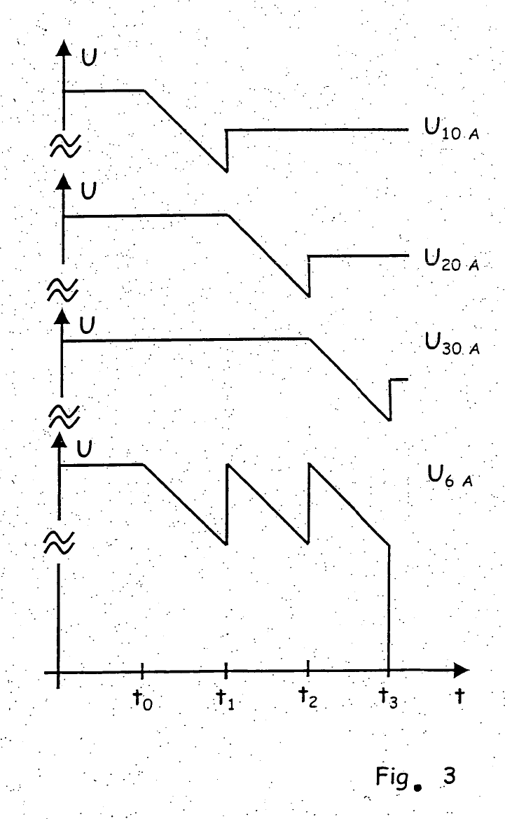

FIG. 3 shows the time curves of the voltages U_{10 A}, U_{20 A}, U_{30 A}, U_{6 A} on the battery lines 10, 20, 30 as well as on an electric load 6 connected to the battery array. The battery line 10 is being discharged to the electric load 6 at time t₀ and it is completely discharged at time t₁, and the battery line 20 is subsequently being discharged to the electric load 6. The battery line 20 is completely discharged at time t₂, and the battery line 30 is subsequently discharged to the electric load 6. The battery line 30 is completely discharged at time t₃. The battery array is now completely discharged. It is not connected to a battery charger 5, so that charging of the battery lines 10, 20, 30 does not take place. The voltage curve U_{6 A} belonging to the electric load 6 is obtained by the superimposition of the voltage curves U_{10 A}, U_{20 A}, U_{30 A}.

While a specific embodiment of the invention has been shown and described in detail to illustrate the application of the principles of the invention, it will be understood that the invention may be embodied otherwise without departing from such principles.

1. A battery array for connection to an electric load as well as to a battery charger, the battery array comprising:
a plurality of said battery lines connected in parallel, each battery line including a plurality of galvanic cells connected in series and a measuring unit associated with each of said battery lines for one or more of estimating the state of charge and measuring values for determining the state of charge of said battery line;
an evaluating and control unit connected with said measuring units for estimating the state of charge and receiving and evaluating said measured values;
a plurality of switches, one of said switches being arranged between each one of said battery lines and said electric load and one of said switches being arranged between each one of said battery lines and said battery charger said switches being actuated by said evaluating and control unit for opening and closing.

2. A battery array in accordance with claim 1, wherein the energy that can be supplied by one of said individual battery lines is selected in adaptation to said electric load that can be connected such that it will be consumed for a typical use of said electric load within a period of time for which the state of charge of said battery line can be reliably determined by said corresponding measuring unit for estimating the state of charge of said battery line.

3. A battery array in accordance with claim 1, wherein said electric load is part of or is connected to a gas-measuring device.

4. A process for controlling the state of charge of a battery array the process comprising the steps:
providing a plurality of the battery lines connected in parallel, each battery line including a plurality of galvanic cells connected in series and a measuring unit associated with each the battery line for one or more of estimating the state of charge and measuring values for determining the state of charge of the battery line;
providing an evaluating and control unit connected with the measuring units for estimating the state of charge and receiving and evaluating the measured values;
providing a plurality of switches, one of the switches being arranged between each one of the battery lines and the electric load and one of the switches being arranged between each one of the battery lines and the battery charger the switches being actuated by the evaluating and control unit for opening and closing;
measuring values with each measuring unit for estimating the state of charge of the respective battery line for determining the state of charge of the corresponding battery line and sending the values to the evaluating and control unit;
calculating a value for the state of charge with the evaluating and control unit from the measured values;
when the battery array is connected to the electric load, selecting with the evaluating and control unit the one of the battery lines with the highest state of charge for releasing charge to the electric load on the basis of the values calculated in said step of calculating by actuating the corresponding switch for closing and actuating the rest of the switches for opening;
when the battery array is connected to a the battery charger, selecting with the evaluating and control unit the battery line with the lowest state of charge for taking up charge from the battery charger on the basis of the values calculated in said step of calculating by actuating the corresponding switch for closing and actuating the rest of the switches for opening;
as soon as the battery line with the highest charge has been completely discharged in the step including releasing charge to the electric load, and the battery line with the lowest charge has been completely charged in the step including taking up charge from the battery charger, a corresponding signal is recognized by the evaluating and control unit and the sequence is started again from the step of measuring values.

5. A process in accordance with claim 4, wherein if more than one of the battery lines has the highest state of charge, the battery line that had been selected to release its charge to the electric load the longest time ago is selected in said step including releasing charge to the electric load.

6. A process in accordance with claim 4, wherein if more than one of the battery lines has the lowest state of charge, the battery line that had been selected to take up charge from the battery charger the longest time ago is selected in the step including taking up charge from the battery charger.

7. A process in accordance with claim 4, wherein said electric load is connected to or is part of a gas-measuring device.

8. A battery array for connection to an electric load as well as to a battery charger, the battery array comprising:
a plurality of battery lines connected in parallel;
a plurality of galvanic cells, each of said galvanic cells being associated and connected with one of said battery lines;
a measuring unit associated with each of said battery lines for measuring values to be used for one or more of estimating the state of charge and for determining the state of charge of the associated battery line;
an evaluating and control unit connected with said measuring units for estimating the state of charge and receiving and evaluating said measured values;
a switching means for switching between an open and closed electrical connection between each one of said battery lines and said electric load and for switching between an open and closed electrical connection between each one of said battery lines and said battery charger said switching means being actuated by said evaluating and control unit for opening and closing.

9. A battery array in accordance with claim 8, wherein said measuring unit measures values for estimating the state of charge of the respective battery line and for determining the state of charge of the corresponding battery line and sends the values to the evaluating and control unit and said evaluating and control unit calculates a value for the state of charge with the from the measured values.

10. A battery array in accordance with claim 9, wherein said evaluating and control unit selects the one of the battery lines with the highest state of charge, when the battery array is connected to a the electric load, for releasing charge to the electric load on the basis of the values calculated by actuating the corresponding switch by closing to provide electrical connection and actuating the rest of the switches by opening to end electrical connection.

11. A battery array in accordance with claim 9, wherein said evaluating and control unit selects the battery line with the lowest state of charge, when the battery array is connected to a the battery charger, for taking up charge from the battery charger on the basis of the valves calculated by actuating the corresponding switch for closing to provide electrical connection and actuating the rest of the switches by opening to end electrical connection.

12. A battery array in accordance with claim 8, wherein the energy that can be supplied by one of said individual battery lines is selected in adaptation to said electric load that can be connected such that it will be consumed for a typical use of said electric load within a period of time for which the state of charge of said battery line can be reliably determined by said corresponding measuring unit for estimating the state of charge of said battery line.

13. A battery array in accordance with claim 8, wherein said electric load can be connected is a gas-measuring device.
